(19) United States
(12) Patent Application Publication
(10) Pub. No.: US 2026/0206391 A1
(43) Pub. Date: Jul. 16, 2026

(54) DISPLAY DEVICE AND ELECTRONIC DEVICE INCLUDING THE SAME

(71) Applicant: Samsung Display Co., Ltd., Yongin-Si (KR)

(72) Inventors: JAEKEUN LIM, Yongin-si (KR); HAE-KWAN SEO, Yongin-si (KR)

(21) Appl. No.: 19/378,324

(22) Filed: Nov. 4, 2025

(30) Foreign Application Priority Data
Jan. 13, 2025 (KR) 10-2025-0004615

(51) Int. Cl. H10H 29/49; G09G 3/00; G09G 3/32

(52) U.S. Cl. CPC H10H 29/49; G09G 3/035; G09G 3/32; G09G 2300/0452; G09G 2300/0819; G09G 2300/0842; G09G 2300/0861; G09G 2310/08; G09G 2380/02

(57) ABSTRACT

A display device includes a display panel including a first display area, a second display area at a first side of the first display area in a first direction, and a third display area at a second side of the first display area in the first direction, data lines arranged in the first direction in the first to third display areas, the data lines extending in a second direction intersecting the first direction, vertical connection lines arranged in the first direction in the first display area, the vertical connection lines extending in the second direction, and horizontal connection lines which connect the vertical connection lines to the data lines in the second or third display area, the horizontal connection lines extending in the first direction. A number ratio of the data lines and the vertical connection lines in the first display area is 1:2.

### CROSS-REFERENCE TO RELATED APPLICATIONS

This application claims priority under 35 USC § 119 to Korean Patent Application No. 10-2025-0004615 filed on January 13, 2025, in the Korean Intellectual Property Office (KIPO), the entire disclosure of which is incorporated by reference herein.

### BACKGROUND

### Field

Embodiments relate to a display device. More particularly, embodiments relate to a foldable display device and an electronic device including the foldable display device.

### Description of the Related Art

A display device may receive image data from a processor or the like, and may display an image corresponding to the image data.

Recently, a foldable display device that may be folded or unfolded as needed is being developed.

### SUMMARY

Embodiments provide a display device of which the area is reduced when folded, and an electronic device including the display device.

A display device according to embodiments includes a display panel including a first display area, a second display area at a first side of the first display area in a first direction, and a third display area at a second side of the first display area in the first direction, data lines arranged in the first direction in the first display area, the second display area, and the third display area, the data lines extending in a second direction intersecting the first direction, vertical connection lines arranged in the first direction in the first display area, the vertical connection lines extending in the second direction, and horizontal connection lines configured to connect the vertical connection lines to the data lines in the second display area or the third display area, the horizontal connection lines extending in the first direction. A number ratio of the data lines and the vertical connection lines in the first display area is 1:2.

In an embodiment, each of line groups may include a data line which is one of the data lines, a first vertical connection line which is one of the vertical connection lines and adjacent to a first side of the data line, and a second vertical connection line which is one of the vertical connection lines and adjacent to a second side of the data line. The line groups may be arranged in the first direction in the first display area.

In an embodiment, the first display area may include a first sub-display area adjacent to the second display area and a second sub-display area adjacent to the third display area. Vertical connection lines in the first sub-display area may be electrically connected to the data lines in the second display area. Vertical connection lines in the second sub-display area may be electrically connected to the data lines in the third display area.

In an embodiment, the display panel may be foldable along a first folding line extending in the second direction between the first display area and the second display area and a second folding line extending in the second direction between the first display area and the third display area.

In an embodiment, a vertical connection line closest to the first folding line among the vertical connection lines in the first sub-display area may be electrically connected to a data line closest to the first folding line among the data lines in the second display area. A vertical connection line farthest from the first folding line among the vertical connection lines in the first sub-display area may be electrically connected to a data line farthest from the first folding line among the data lines in the second display area.

In an embodiment, a vertical connection line closest to the second folding line among the vertical connection lines in the second sub-display area may be electrically connected to a data line closest to the second folding line among the data lines in the third display area. A vertical connection line farthest from the second folding line among the vertical connection lines in the second sub-display area may be electrically connected to a data line farthest from the second folding line among the data lines in the third display area.

In an embodiment, a number of data lines in the first display area, a number of data lines in the second display area, and a number of data lines in the third display area may be the same.

In an embodiment, each of the data lines may be connected to a first pixel and a second pixel in one pixel row.

In an embodiment, each of the first pixel and the second pixel may include a light-emitting element, a first transistor configured to generate a driving current flowing to the light-emitting element, a second transistor configured to transmit a data voltage to a first terminal of the first transistor, and a storage capacitor connected to a gate of the first transistor. The second transistor of the first pixel may be configured to transmit the data voltage to the first terminal of the first transistor of the first pixel in response to a first write gate signal. The second transistor of the second pixel may be configured to transmit the data voltage to the first terminal of the first transistor of the second pixel in response to a second write gate signal.

In an embodiment, the second write gate signal may be a signal in which the first write gate signal is shifted by a selected time.

In an embodiment, each of the first pixel and the second pixel may further include a third transistor configured to connect the gate and a second terminal of the first transistor in response to a compensation gate signal, a fourth transistor configured to transmit a first initialization voltage to the gate of the first transistor in response to an initialization gate signal, a fifth transistor configured to transmit a first power voltage to the first terminal of the first transistor in response to an emission signal, a sixth transistor configured to connect the second terminal of the first transistor to a first terminal of the light-emitting element in response to the emission signal, and a seventh transistor configured to transmit a second initialization voltage to the first terminal of the light-emitting element in response to the compensation gate signal of the initialization gate signal.

In an embodiment, the second pixel may be a blue pixel and the first pixel may be a red pixel. The second pixel may be a green pixel and the first pixel may be the green pixel.

In an embodiment, the display device may further include a data driving circuit positioned in the second direction from the first display area and electrically connected to the data lines in the first display area and the vertical connection lines.

A display device according to embodiments includes a display panel including a first display area and a second display area at a side of the first display area in a first direction, data lines arranged in the first direction in the first display area and the second display area, the data lines extending in a second direction intersecting the first direction, vertical connection lines arranged in the first direction in a sub-display area of the first display area adjacent to the second display area, the vertical connection lines extending in the second direction, and horizontal connection lines configured to connect the vertical connection lines to the data lines in the second display area, the horizontal connection lines extending in the first direction. A number ratio of data lines and the vertical connection lines in the sub-display area is 1:2.

In an embodiment, each of line groups may include a data line which is one of the data lines, a first vertical connection line which is one of the vertical connection lines and adjacent to a first side of the data line, and a second vertical connection line which is one of the vertical connection lines and adjacent to a second side of the data line. The line groups may be arranged in the first direction in the sub-display area.

In an embodiment, the display panel may be foldable along a folding line extending in the second direction between the first display area and the second display area.

In an embodiment, a vertical connection line closest to the folding line among the vertical connection lines may be electrically connected to a data line closest to the folding line among the data lines in the second display area. A vertical connection line farthest from the folding line among the vertical connection lines may be electrically connected to a data line farthest from the folding line among the data lines in the second display area.

In an embodiment, a number of data lines in the first display area and a number of data lines in the second display area may be the same.

In an embodiment, the display device may further include a data driving circuit positioned in the second direction from the first display area and electrically connected to the data lines in the first display area and the vertical connection lines.

An electronic device according to embodiments includes one or more processors, a memory connected to the one or more processors, a power module connected to the one or more processors, and a display device configured to receive input image data from the one or more processors and to display an image corresponding to the input image data. The display device includes a display panel including a first display area, a second display area at a first side of the first display area in a first direction, and a third display area at a second side of the first display area in the first direction, data lines arranged in the first direction in the first display area, the second display area, and the third display area, the data lines extending in a second direction intersecting the first direction, vertical connection lines arranged in the first direction in the first display area, the vertical connection lines extending in the second direction, and horizontal connection lines configured to connect the vertical connection lines to the data lines in the second display area or the third display area, the horizontal connection lines extending in the first direction. A number ratio of the data lines and the vertical connection lines in the first display area is 1:2.

In the display device and the electronic device according to the embodiments, the number ratio of the data lines in the first display area and the vertical connection lines is 1:2, so that the first display area, the second display area, and the third display area of the display panel may have an area ratio of 1:1:1, and the area of the display device may be reduced when the display device is folded.

### BRIEF DESCRIPTION OF THE DRAWINGS

Illustrative, non-limiting embodiments will be more clearly understood from the following detailed description taken in conjunction with the accompanying drawings.

FIG. 1 is a block diagram illustrating a display device according to an embodiment.

FIGS. 2 and 3 are perspective views illustrating the display device of FIG. 1.

FIG. 4 is a plan view illustrating the display device of FIGS. 2 and 3.

FIG. 5 is a plan view illustrating the display device of FIG. 4.

FIG. 6 is a circuit diagram illustrating a first pixel and a second pixel included in the display device of FIG. 4.

FIG. 7 is a timing diagram illustrating signals and a data voltage of the first pixel and the second pixel of FIG. 6.

FIGS. 8 and 9 are perspective views illustrating a display device according to an embodiment.

FIG. 10 is a plan view illustrating the display device of FIGS. 8 and 9.

FIG. 11 is a block diagram illustrating an electronic device according to an embodiment.

FIG. 12 is a diagram illustrating electronic devices according to embodiments.

### DETAILED DESCRIPTION OF THE EMBODIMENTS

Hereinafter, a display device and an electronic device according to embodiments of the present disclosure will be described in more detail with reference to the accompanying drawings. The same or similar reference numerals will be used for the same elements in the accompanying drawings.

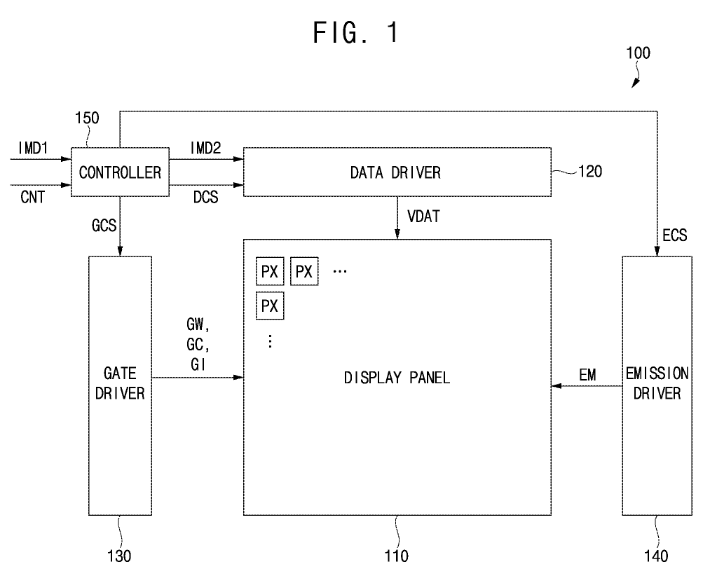

Hereinafter, a display device 100 according to an embodiment will be described with reference to FIGS. 1 to 7.

FIG. 1 is a block diagram illustrating the display device 100 according to an embodiment.

Referring to FIG. 1, the display device 100 may include a display panel 110, a data driver 120, a gate driver 130, an emission driver 140, and a controller 150.

The display panel 110 may include pixels PX. The display panel 110 may display an image based on light emitted from each of the pixels PX. In an embodiment, the pixels PX may include red pixels that emit red light, green pixels that emit green light, and blue pixels that emit blue light.

The data driver 120 may provide a data voltage VDAT to each of the pixels PX. The data driver 120 may generate the data voltage VDAT based on output image data IMD2 and a data control signal DCS. The data driver 120 may convert the output image data IMD2 in digital format into the data voltage VDAT in analog format. The data control signal DCS may include a load signal, an output data enable signal, a data clock signal, etc.

The gate driver 130 may provide a write gate signal GW, a compensation gate signal GC, and an initialization gate signal GI to each of the pixels PX. The gate driver 130 may generate the write gate signal GW, the compensation gate signal GC, and the initialization gate signal GI based on a gate control signal GCS. The gate control signal GCS may include a gate start signal, a gate clock signal, etc.

The emission driver 140 may provide an emission signal EM to each of the pixels PX. The emission driver 140 may generate the emission signal EM based on an emission control signal ECS. The emission control signal ECS may include an emission start signal, an emission clock signal, etc.

The controller 150 may control the data driver 120, the gate driver 130, and the emission driver 140. The controller 150 may provide the output image data IMD2 and the data control signal DCS to the data driver 120, may provide the gate control signal GCS to the gate driver 130, and may provide the emission control signal ECS to the emission driver 140. The controller 150 may generate the output image data IMD2, the data control signal DCS, the gate control signal GCS, and the emission control signal ECS based on input image data IMD1 and a control signal CNT. The controller 150 may convert the input image data IMD1 into the output image data IMD2. The control signal CNT may include a vertical synchronization signal, a horizontal synchronization signal, an input data enable signal, a master clock signal, etc.

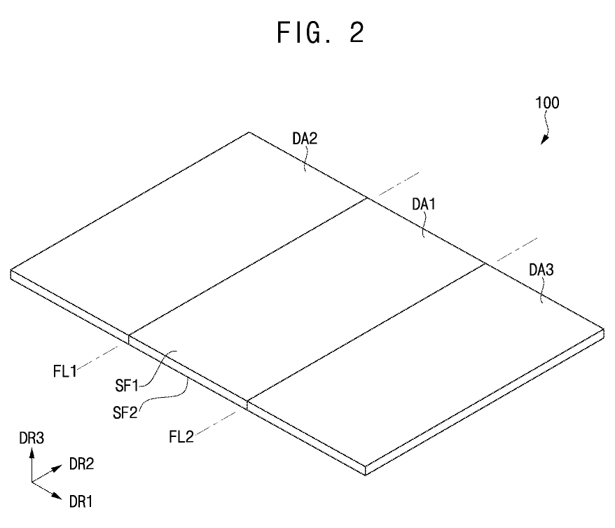

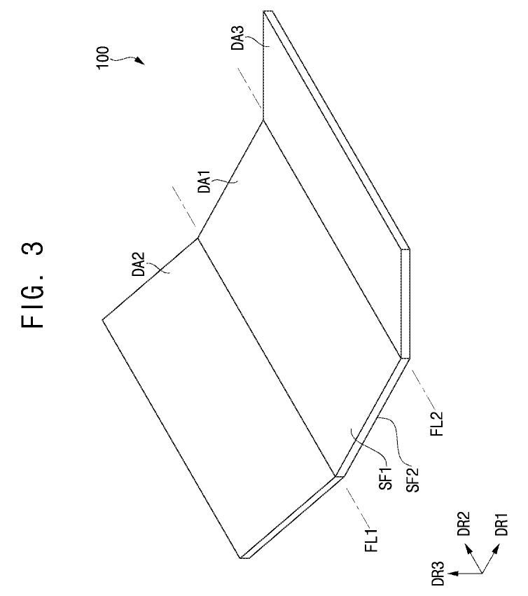

FIGS. 2 and 3 are perspective views illustrating the display device 100 of FIG. 1.

Referring to FIGS. 1 to 3, the display device 100 may include a first display area DA1, a second display area DA2, and a third display area DA3. The second display area DA2 may be positioned at a first side of the first display area DA1 in a first direction DR1. The third display area DA3 may be positioned at a second side of the first display area DA1 in the first direction DR1. The second side of the first display area DA1 may be opposite to the first side of the first display area DA1 in the first direction DR1.

The display device 100 may be folded along a first folding line FL1 and a second folding line FL2. The first folding line FL1 may extend in a second direction DR2 between the first display area DA1 and the second display area DA2. The second direction DR2 may intersect the first direction DR1. The second folding line FL2 may extend in the second direction DR2 between the second display area DA2 and the third display area DA3.

The display device 100 may be folded along the first folding line FL1 so that a first surface SF1 of the first display area DA1 and the first surface SF1 of the second display area DA2 face each other, or a second surface SF2 of the first display area DA1 and the second surface SF2 of the second display area DA2 face each other. The second surface SF2 of the display device 100 may be opposite to the first surface SF1 of the display device 100 in a third direction DR3 intersecting the first direction DR1 and the second direction DR2.

The display device 100 may be folded along the second folding line FL2 so that the first surface SF1 of the first display area DA1 and the first surface SF1 of the third display area DA3 face each other, or the second surface SF2 of the first display area DA1 and the second surface SF2 of the third display area DA3 face each other.

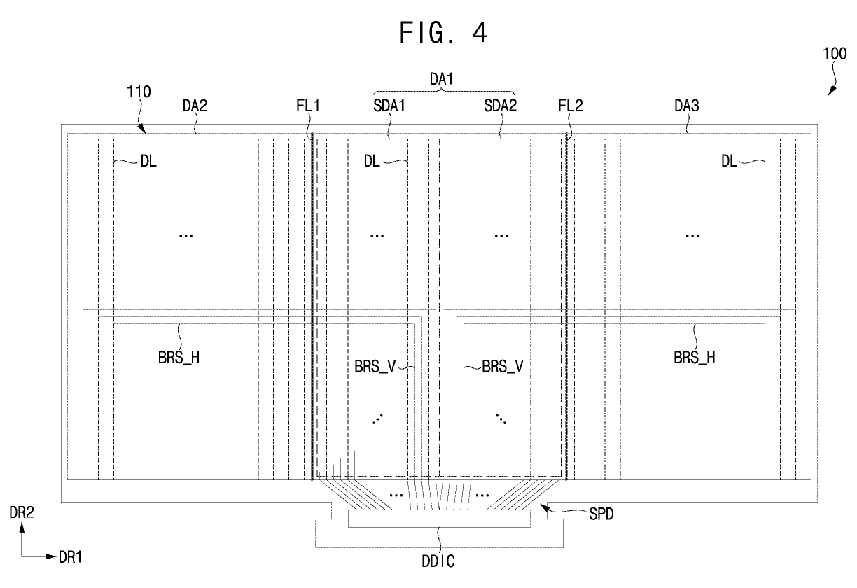

FIG. 4 is a plan view illustrating the display device 100 of FIGS. 2 and 3.

Referring to FIGS. 1 to 4, the display device 100 may include the display panel 110, data lines DL, vertical connection lines BRS_V, horizontal connection lines BRS_H, and a data driving circuit DDIC.

The display panel 110 may include the first display area DA1, the second display area DA2, and the third display area DA3. The first display area DA1 may include a first sub-display area SDA1 adjacent to the second display area DA2 and a second sub-display area SDA2 adjacent to the third display area DA3. The display panel 110 may be folded along the first folding line FL1 and the second folding line FL2.

The data lines DL may be arranged in the first direction DR1 in the first display area DA1, the second display area DA2, and the third display area DA3, and may extend in the second direction DR2. Each of the data lines DL may transmit the data voltage VDAT to the pixel PX.

The vertical connection lines BRS_V may be arranged in the first direction DR1 in the first display area DA1, and may extend in the second direction DR2. Each of the vertical connection lines BRS_V may transmit the data voltage VDAT to the data line DL in the second display area DA2 or the data line DL in the third display area DA3.

The vertical connection lines BRS_V in the first sub-display area SDA1 may be electrically connected to the data lines DL in the second display area DA2, and the vertical connection lines BRS_V in the second sub-display area SDA2 may be electrically connected to the data lines DL in the third display area DA3.

The horizontal connection lines BRS_H may connect the vertical connection lines BRS_V to the data lines DL in the second display area DA2 or the third display area DA3, and may extend in the first direction DR1. The horizontal connection lines BRS_H in the first sub-display area SDA1 and the second display area DA2 may connect the vertical connection lines BRS_V in the first sub-display area SDA1 to the data lines DL in the second display area DA2. The horizontal connection lines BRS_H in the second sub-display area SDA2 and the third display area DA3 may connect the vertical connection lines BRS_V in the second sub-display area SDA2 to the data lines DL in the third display area DA3.

The number of data lines DL in the first display area DA1, the number of data lines DL in the second display area DA2, and the number of data lines DL in the third display area DA3 may be the same. For example, each of the number of data lines DL in the first display area DA1, the number of data lines DL in the second display area DA2, and the number of data lines DL in the third display area DA3 may be 928. In this case, a width of the first display area DA1 in the first direction DR1, a width of the second display area DA2 in the first direction DR1, and a width of the third display area DA3 in the first direction DR1 may be substantially the same.

A number ratio of the data lines DL in the first display area DA1 and the vertical connection lines BRS_V may be 1:2. For example, the number of vertical connection lines BRS_V may be 1856.

In an embodiment, a vertical connection line BRS_V closest to the first folding line FL1 among the vertical connection lines BRS_V in the first sub-display area SDA1 may be electrically connected to a data line DL closest to the first folding line FL1 among the data lines DL in the second display area DA2. A vertical connection line BRS_V farthest from the first folding line FL1 among the vertical connection lines BRS_V in the first sub-display area SDA1 may be electrically connected to a data line DL farthest from the first folding line FL1 among the data lines DL in the second display area DA2.

In an embodiment, a vertical connection line BRS_V closest to the second folding line FL2 among the vertical connection lines BRS_V in the second sub-display area SDA2 may be electrically connected to a data line DL closest to the second folding line FL2 among the data lines DL in the third display area DA3. A vertical connection line BRS_V farthest from the second folding line FL2 among the vertical connection lines BRS_V in the second sub-display area SDA2 may be electrically connected to a data line DL farthest from the second folding line FL2 among the data lines DL in the third display area DA3.

The data driving circuit DDIC may be positioned in the second direction DR2 from the first display area DA1. The data driving circuit DDIC may be electrically connected to the data lines DL in the first display area DA1 and the vertical connection lines BRS_V. The data driving circuit DDIC may include channels that output the data voltages VDAT transmitted to the data lines DL in the first display area DA1 and the vertical connection lines BRS_V. For example, the number of channels may be 2784.

In an embodiment, the data driver 120 may be implemented as the data driving circuit DDIC. In an embodiment, the data driver 120 and the controller 150 may be implemented as the data driving circuit DDIC.

Spider lines SPD may connect the channels of the data driving circuit DDIC to the data lines DL in the first display area DA1 and vertical connection lines BRS_V. The number of spider lines SPD may be the same as the number of channels of the data driving circuit DDIC.

The data lines DL in the second display area DA2 and the third display area DA3 may receive the data voltages VDAT from the data driving circuit DDIC through the vertical connection lines BRS_V and the horizontal connection lines BRS_H. The spider lines SPD may extend from the data driving circuit DDIC only toward the first display area DA1 and may not extend toward the second display area DA2 and the third display area DA3. Accordingly, an area of the non-display area of the display panel 110 surrounding the first to third display areas DA1, DA2, and DA3 may be reduced.

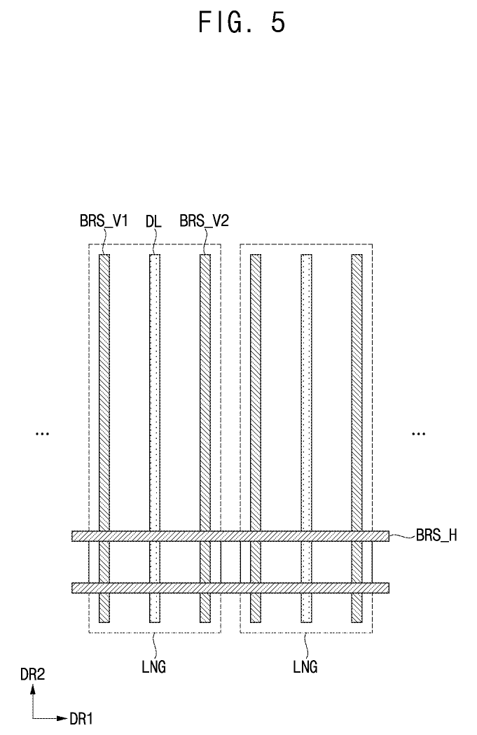

FIG. 5 is a plan view illustrating the display device 100 of FIG. 4.

Referring to FIGS. 4 and 5, the display device 100 may include line groups LNG arranged in the first direction DR1 in the first display area DA1. Each of the line groups LNG may include a data line DL which is one of the data lines DL, a first vertical connection line BRS_V1 which is one of the vertical connection lines BRS_V and adjacent to a first side of the data line DL, and a second vertical connection line BRS_V2 which is one of the vertical connection lines BRS_V and adjacent to a second side of the data line DL. The second side of the data line DL may be opposite to the first side of the data line DL in the first direction DR1.

Each of the vertical connection lines BRS_V may contact a corresponding horizontal connection line BRS_H at a portion intersecting the corresponding horizontal connection line BRS_H. In an embodiment, the vertical connection lines BRS_V and the horizontal connection lines BRS_H may have a one-to-one correspondence.

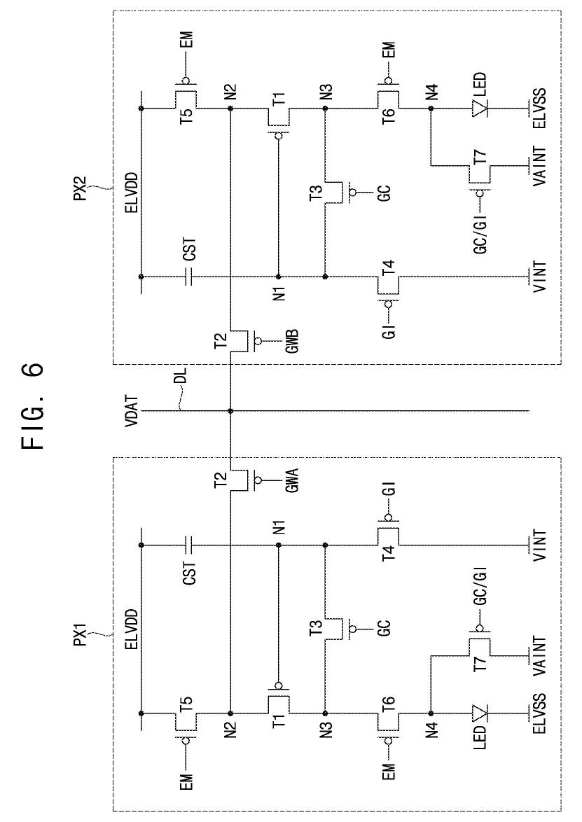

FIG. 6 is a circuit diagram illustrating a first pixel PX1 and a second pixel PX2 included in the display device 100 of FIG. 4.

Referring to FIGS. 4 and 6, the first pixel PX1 and the second pixel PX2 may be positioned in one pixel row, and the data line DL may be connected to the first pixel PX1 and the second pixel PX2. In other words, the first pixel PX1 and the second pixel PX2 positioned in one pixel row may share one data line DL. The first pixel PX1 and the second pixel PX2 positioned in one pixel row may share one data line DL, so that the number of data lines DL included in the display device 100 may be reduced, and the number of channels of the data driving circuit DDIC may be reduced.

In an embodiment, the second pixel PX2 may be a blue pixel and the first pixel PX1 may be a red pixel, and the second pixel PX2 may be a green pixel and the first pixel PX1 may be the green pixel.

Each of the first pixel PX1 and the second pixel PX2 may include a light-emitting element LED, a first transistor T1, a second transistor T2, a third transistor T3, a fourth transistor T4, a fifth transistor T5, a sixth transistor T6, a seventh transistor T7, and a storage capacitor CST.

The light-emitting element LED may emit light with a luminance corresponding to a driving current. The light-emitting element LED may include a first terminal (e.g., an anode) connected to a fourth node N4 and a second terminal (e.g., a cathode) that receives a second power voltage ELVSS.

The first transistor T1 may generate the driving current flowing to the light-emitting element LED. The first transistor T1 may include a gate connected to a first node N1, a first terminal connected to a second node N2, and a second terminal connected to a third node N3. One of the first terminal and the second terminal of the first transistor T1 may be a source, and the other of the first terminal and the second terminal of the first transistor T1 may be a drain.

The second transistor T2 may transmit the data voltage VDAT to the first terminal of the first transistor T1. The second transistor T2 of the first pixel PX1 may transmit the data voltage VDAT to the second node N2 of the first pixel PX1 in response to a first write gate signal GWA. The second transistor T2 of the first pixel PX1 may include a gate that receives the first write gate signal GWA, a first terminal connected to the data line DL, and a second terminal connected to the second node N2 of the first pixel PX1. The second transistor T2 of the second pixel PX2 may transmit the data voltage VDAT to the second node N2 of the second pixel PX2 in response to a second write gate signal GWB. The second transistor T2 of the second pixel PX2 may include a gate that receives the second write gate signal GWB, a first terminal connected to the data line DL, and a second terminal connected to the second node N2 of the second pixel PX2. One of the first terminal and the second terminal of the second transistor T2 may be a source, and the other of the first terminal and the second terminal of the second transistor T2 may be a drain.

The third transistor T3 may connect the gate and the second terminal of the first transistor T1 in response to the compensation gate signal GC. The third transistor T3 may include a gate that receives the compensation gate signal GC, a first terminal connected to the first node N1, and a second terminal connected to the third node N3. One of the first terminal and the second terminal of the third transistor T3 may be a source, and the other of the first terminal and the second terminal of the third transistor T3 may be a drain.

The fourth transistor T4 may transmit a first initialization voltage VINT to the gate of the first transistor T1 in response to the initialization gate signal GI. The fourth transistor T4 may include a gate that receives the initialization gate signal GI, a first terminal that receives the first initialization voltage VINT, and a second terminal connected to the first node N1. One of the first terminal and the second terminal of the fourth transistor T4 may be a source, and the other of the first terminal and the second terminal of the fourth transistor T4 may be a drain.

The fifth transistor T5 may transmit a first power voltage ELVDD to the first terminal of the first transistor T1 in response to the emission signal EM. The fifth transistor T5 may include a gate that receives the emission signal EM, a first terminal that receives the first power voltage ELVDD, and a second terminal connected to the second node N2. One of the first terminal and the second terminal of the fifth transistor T5 may be a source, and the other of the first terminal and the second terminal of the fifth transistor T5 may be a drain.

The sixth transistor T6 may connect the second terminal of the first transistor T1 to the first terminal of the light-emitting element LED in response to the emission signal EM. The sixth transistor T6 may include a gate that receives the emission signal EM, a first terminal connected to the third node N3, and a second terminal connected to the fourth node N4. One of the first terminal and the second terminal of the sixth transistor T6 may be a source, and the other of the first terminal and the second terminal of the sixth transistor T6 may be a drain.

The seventh transistor T7 may transmit a second initialization voltage VAINT to the first terminal of the light-emitting element LED in response to the compensation gate signal GC or the initialization gate signal GI. The seventh transistor T7 may include a gate that receives the compensation gate signal GC or the initialization gate signal GI, a first terminal that receives the second initialization voltage VAINT, and a second terminal connected to the fourth node N4. One of the first terminal and the second terminal of the seventh transistor T7 may be a source, and the other of the first terminal and the second terminal of the seventh transistor T7 may be a drain.

The storage capacitor CST may be connected between the gate of the first transistor T1 and a line that transmits the first power voltage ELVDD. The storage capacitor CST may include a first terminal connected to the first node N1 and a second terminal that receives the first power voltage ELVDD.

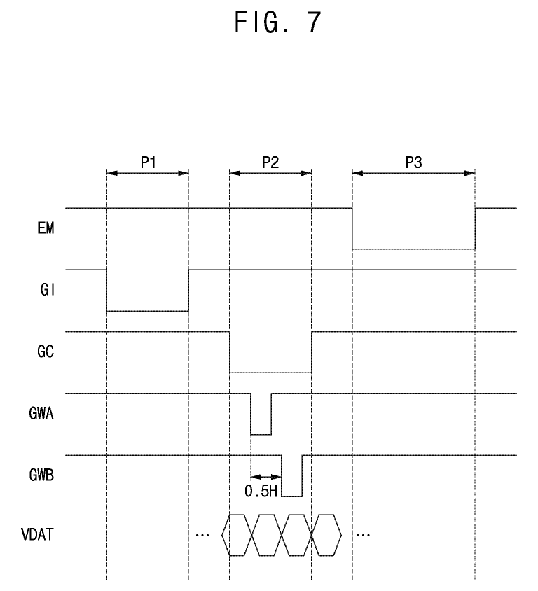

FIG. 7 is a timing diagram illustrating the signals EM, GI, GC, GWA, and GWB and the data voltage VDAT of the first pixel PX1 and the second pixel PX2 of FIG. 6.

Referring to FIGS. 6 and 7, in a first period P1, the fourth transistor T4 may be turned on in response to the initialization gate signal GI, and the first initialization voltage VINT may be applied to the first node N1. Accordingly, a channel may be formed in the first transistor T1 in the first period P1. When the gate of the seventh transistor T7 receives the initialization gate signal GI, in the first period P1, the seventh transistor T7 may be turned on in response to the initialization gate signal GI, and the second initialization voltage VAINT may be applied to the fourth node N4.

In a second period P2, the third transistor T3 may be turned on in response to the compensation gate signal GC, and the gate and the second terminal of the first transistor T1 may be connected. Accordingly, in the second period P2, the first transistor T1 may be diode-connected. When the gate of the seventh transistor T7 receives the compensation gate signal GC in the second period P2, the seventh transistor T7 may be turned on in response to the compensation gate signal GC, and the second initialization voltage VAINT may be applied to the fourth node N4.

In the second period P2, the second transistor T2 of the first pixel PX1 may be turned on in response to the first write gate signal GWA, and the data voltage VDAT may be applied to the first terminal of the first transistor T1 of the first pixel PX1. In the second period P2, since the first transistor T1 is diode-connected, the data voltage VDAT in which a threshold voltage of the first transistor T1 of the first pixel PX1 is compensated may be applied to the gate of the first transistor T1 of the first pixel PX1.

In the second period P2, the second transistor T2 of the second pixel PX2 may be turned on in response to the second write gate signal GWB, and the data voltage VDAT may be applied to the first terminal of the first transistor T1 of the second pixel PX2. The second write gate signal GWB may be a signal in which the first write gate signal GWA is shifted by a selected time. For example, the second write gate signal GWB may be a signal in which the first write gate signal GWA is shifted by half 0.5H of one horizontal time period. Since the first transistor T1 is diode-connected in the second period P2, the data voltage VDAT in which the threshold voltage of the first transistor T1 of the second pixel PX2 is compensated may be applied to the gate of the first transistor T1 of the second pixel PX2.

In a third period P3, the fifth transistor T5 and the sixth transistor T6 may be turned on in response to the emission signal EM, and the driving current generated in the first transistor T1 may flow to the light-emitting element LED. Accordingly, in the third period P3, the light-emitting element LED may emit light with a luminance corresponding to the driving current.

In the prior art, the number ratio of the data lines in the first display area and the vertical connection lines may be 1:1. Since the data lines in the second display area and the data lines in the third display area are connected to the vertical connection lines, in the prior art, the first display area, the second display area, and the third display area of the display panel may have an area ratio of 2:1:1. In the prior art, the area of the first display area may be equal to the sum of the area of the second display area and the area of the third display area, and accordingly, the area of the display device may increase when the display device is folded.

In the embodiments, the number ratio of the data lines DL in the first display area DA1 and the vertical connection lines BRS_V is 1:2, so that the first display area DA1, the second display area DA2, and the third display area DA3 of the display panel 110 may have an area ratio of 1:1:1. The area of the first display area DA1 may be equal to the area of second/third display area DA2/DA3, and accordingly, the area of the display device 100 may be reduced when the display device 100 is folded.

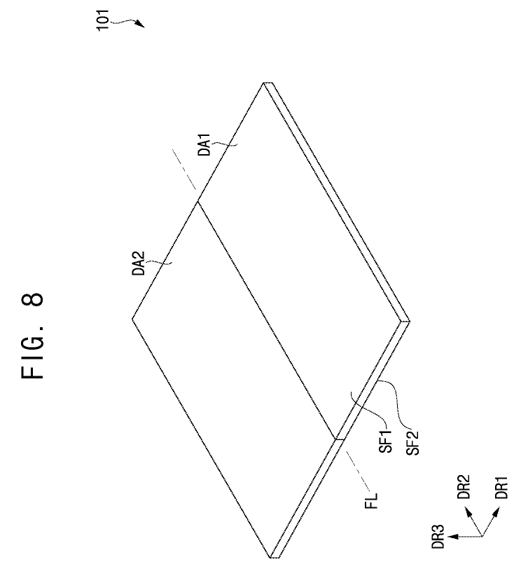

Hereinafter, a display device 101 according to an embodiment will be described with reference to FIGS. 8 to 10. The display device 101 described with reference to FIGS. 8 to 10 may be substantially the same as or similar to the display device 100 described with reference to FIGS. 1 to 7, except for not including the third display area DA3.

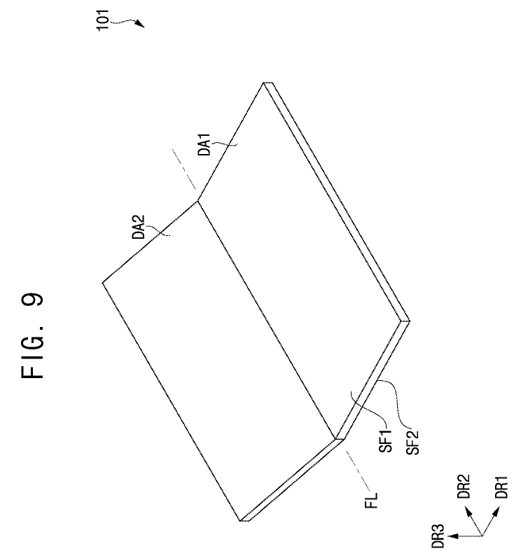

FIGS. 8 and 9 are perspective views illustrating the display device 101 according to an embodiment.

Referring to FIGS. 8 and 9, the display device 101 may include a first display area DA1 and a second display area DA2. The second display area DA2 may be positioned at one side of the first display area DA1 in a first direction DR1.

The display device 101 may be folded along a folding line FL. The folding line FL may extend in a second direction DR2 between the first display area DA1 and the second display area DA2. The second direction DR2 may intersect the first direction DR1.

The display device 101 may be folded along the folding line FL so that a first surface SF1 of the first display area DA1 and the first surface SF1 of the second display area DA2 face each other, or a second surface SF2 of the first display area DA1 and the second surface SF2 of the second display area DA2 face each other. The second surface SF2 of the display device 100 may be opposite to the first surface SF1 of the display device 100 in a third direction DR3 intersecting the first direction DR1 and the second direction DR2.

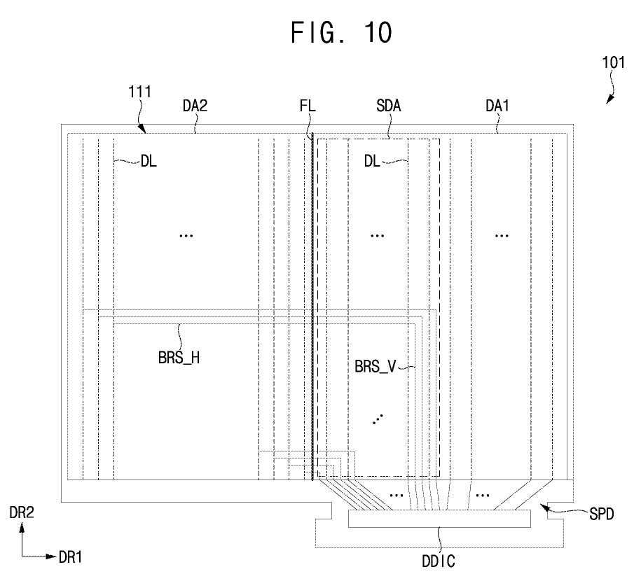

FIG. 10 is a plan view illustrating the display device 101 of FIGS. 8 and 9.

Referring to FIGS. 8 to 10, the display device 101 may include a display panel 111, data lines DL, vertical connection lines BRS_V, horizontal connection lines BRS_H, and a data driving circuit DDIC.

The display panel 111 may include the first display area DA1 and the second display area DA2. The first display area DA1 may include a sub-display area SDA adjacent to the second display area DA2. The display panel 110 may be folded along the folding line FL.

The data lines DL may be arranged in the first direction DR1 in the first display area DA1 and the second display area DA2, and may extend in the second direction DR2. Each of the data lines DL may transmit a data voltage to a pixel.

The vertical connection lines BRS_V may be arranged in the first direction DR1 in the sub-display area SDA, and may extend in the second direction DR2. Each of the vertical connection lines BRS_V may transmit the data voltage to the data line DL in the second display area DA2. The vertical connection lines BRS_V may be electrically connected to the data lines DL in the second display area DA2.

The horizontal connection lines BRS_H may connect the vertical connection lines BRS_V to the data lines DL in the second display area DA2, and may extend in the first direction DR1.

The number of data lines DL in the first display area DA1 and the number of data lines DL in the second display area DA2 may be the same. For example, each of the number of data lines DL in the first display area DA1 and the number of data lines DL in the second display area DA2 may be 928. In this case, a width of the first display area DA1 in the first direction DR1 and a width of the second display area DA2 in the first direction DR1 may be substantially the same.

A number ratio of the data lines DL in the sub-display area SDA and the vertical connection lines BRS_V may be 1:2. For example, the number of vertical connection lines BRS_V may be 928.

In an embodiment, a vertical connection line BRS_V closest to the folding line FL among the vertical connection lines BRS_V may be electrically connected to a data line DL closest to the folding line FL among the data lines DL in the second display area DA2, and a vertical connection line BRS_V farthest from the folding line FL among the vertical connection lines BRS_V may be electrically connected to a data line DL farthest from the folding line FL among the data lines DL in the second display area DA2.

The data driving circuit DDIC may be positioned in the second direction DR2 from the first display area DA1. The data driving circuit DDIC may be electrically connected to the data lines DL in the first display area DA1 and the vertical connection lines BRS_V. The data driving circuit DDIC may include channels that output data voltages transmitted to data lines DL in the first display area DA1 and the vertical connection lines BRS_V. For example, the number of channels may be 1856.

Spider lines SPD may connect the channels of the data driving circuit DDIC to the data lines DL in the first display area DA1 and the vertical connection lines BRS_V. The number of spider lines SPD may be the same as the number of channels of the data driving circuit DDIC.

As illustrated in FIG. 5, the display device 101 may include line groups LNG arranged in the first direction DR1 in the sub-display area SDA. Each of the line groups LNG may include a data line DL which is one of the data lines DL, a first vertical connection line BRS_V1 which is one of the vertical connection lines BRS_V and adjacent to a first side of the data line DL, and a second vertical connection line BRS_V2 which is one of the vertical connection lines BRS_V and adjacent to a second side of the data line DL.

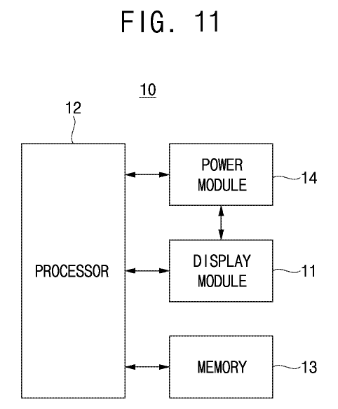

FIG. 11 is a block diagram illustrating an electronic device 10 according to an embodiment.

Referring to FIG. 11, the electronic device 10 may include a display module 11, a processor 12, a memory 13, and a power module 14.

The processor 12 may include one or more processors and may include at least one of a central processing unit (CPU), an application processor (AP), a graphic processing unit (GPU), a communication processor (CP), an image signal processor (ISP), and a controller. The processor may control the display module 11.

The memory 13 may store data information necessary for an operation of the processor 12 or the display module 11. When the processor 12 executes an application stored in the memory 13, the input image data IMD1 of FIG. 1 and the control signal CNT of FIG. 1 may be transmitted to the display module 11, and the display module 11 may output image information based on the input image data IMD1 and the control signal CNT.

The power module 14 may include a power supply module such as a power adapter, a battery device, etc. and a power conversion module that converts power supplied by the power supply module to generate power required for an operation of the electronic device 10.

At least one of the components of the electronic device 10 described above may be included in the display device 100 of FIG. 1 according to the embodiments described above. Further, some of individual modules functionally included in one module may be included in the display device 100, and others may be provided separately from the display device 100. For example, the display device 100 may include the display module 11, and the processor 12, the memory 13, and the power module 14 may be provided in the form of other devices within the electronic device 11 other than the display device 100.

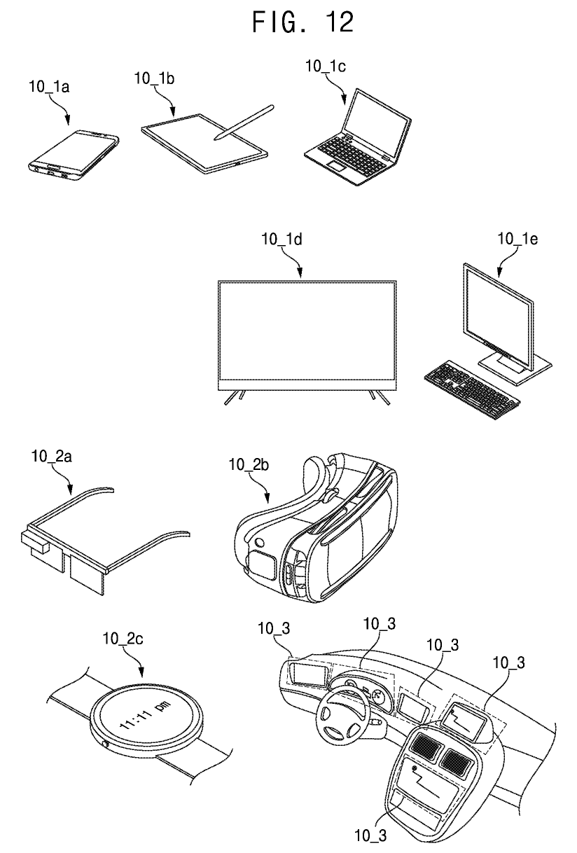

FIG. 12 is a diagram illustrating electronic devices according to embodiments.

Referring to FIG. 12, electronic devices to which display devices according to embodiments are applied may include not only image display electronic devices such as a smart phone 10_1a, a tablet PC 10_1b, a laptop 10_1c, a TV 10_1d, a desk monitor 10_1e, etc. but also wearable electronic devices including display modules such as smart glasses 10_2a, a head mounted display 10_2b, a smart watch 10_2c, etc., vehicle electronic devices 10_3 including display modules such as an instrument panel of an automobile, a center fascia, a center information display CID arranged on a dashboard, a room mirror display, etc.

The display device according to the embodiments may be applied to a display device included in a computer, a notebook, a mobile phone, a smart phone, a smart pad, a smart watch, a PMP, a PDA, an MP3 player, or the like.

Although the display device and the electronic device according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a display panel including a first display area, a second display area at a first side of the first display area in a first direction, and a third display area at a second side of the first display area in the first direction;
data lines arranged in the first direction in the first display area, the second display area, and the third display area, the data lines extending in a second direction intersecting the first direction;
vertical connection lines arranged in the first direction in the first display area, the vertical connection lines extending in the second direction; and
horizontal connection lines configured to connect the vertical connection lines to the data lines in the second display area or the third display area, the horizontal connection lines extending in the first direction,
wherein a number ratio of the data lines and the vertical connection lines in the first display area is 1:2.

2. The display device of claim 1, wherein each of line groups includes a data line which is one of the data lines, a first vertical connection line which is one of the vertical connection lines and adjacent to a first side of the data line, and a second vertical connection line which is one of the vertical connection lines and adjacent to a second side of the data line, and
wherein the line groups are arranged in the first direction in the first display area.

3. The display device of claim 1, wherein the first display area includes a first sub-display area adjacent to the second display area and a second sub-display area adjacent to the third display area,
wherein vertical connection lines in the first sub-display area are electrically connected to the data lines in the second display area, and
wherein vertical connection lines in the second sub-display area are electrically connected to the data lines in the third display area.

4. The display device of claim 3, wherein the display panel is foldable along a first folding line extending in the second direction between the first display area and the second display area and a second folding line extending in the second direction between the first display area and the third display area.

5. The display device of claim 4, wherein a vertical connection line closest to the first folding line among the vertical connection lines in the first sub-display area is electrically connected to a data line closest to the first folding line among the data lines in the second display area, and
wherein a vertical connection line farthest from the first folding line among the vertical connection lines in the first sub-display area is electrically connected to a data line farthest from the first folding line among the data lines in the second display area.

6. The display device of claim 4, wherein a vertical connection line closest to the second folding line among the vertical connection lines in the second sub-display area is electrically connected to a data line closest to the second folding line among the data lines in the third display area, and
wherein a vertical connection line farthest from the second folding line among the vertical connection lines in the second sub-display area is electrically connected to a data line farthest from the second folding line among the data lines in the third display area.

7. The display device of claim 1, wherein a number of the data lines in the first display area, a number of the data lines in the second display area, and a number of the data lines in the third display area are the same.

8. The display device of claim 1, wherein each of the data lines is connected to a first pixel and a second pixel in one pixel row.

9. The display device of claim 8, wherein each of the first pixel and the second pixel includes:
a light-emitting element;
a first transistor configured to generate a driving current flowing to the light-emitting element;
a second transistor configured to transmit a data voltage to a first terminal of the first transistor; and
a storage capacitor connected to a gate of the first transistor,
wherein the second transistor of the first pixel is configured to transmit the data voltage to the first terminal of the first transistor of the first pixel in response to a first write gate signal, and
wherein the second transistor of the second pixel is configured to transmit the data voltage to the first terminal of the first transistor of the second pixel in response to a second write gate signal.

10. The display device of claim 9, wherein the second write gate signal is a signal in which the first write gate signal is shifted by a selected time.

11. The display device of claim 9, wherein each of the first pixel and the second pixel further includes:
a third transistor configured to connect the gate and a second terminal of the first transistor in response to a compensation gate signal;
a fourth transistor configured to transmit a first initialization voltage to the gate of the first transistor in response to an initialization gate signal;
a fifth transistor configured to transmit a first power voltage to the first terminal of the first transistor in response to an emission signal;
a sixth transistor configured to connect the second terminal of the first transistor to a first terminal of the light-emitting element in response to the emission signal; and
a seventh transistor configured to transmit a second initialization voltage to the first terminal of the light-emitting element in response to the compensation gate signal of the initialization gate signal.

12. The display device of claim 8, wherein the second pixel is a blue pixel and the first pixel is a red pixel, and
wherein the second pixel is a green pixel and the first pixel is the green pixel.

13. The display device of claim 1, further comprising:
a data driving circuit positioned in the second direction from the first display area and electrically connected to the data lines in the first display area and the vertical connection lines.

14. A display device comprising:
a display panel including a first display area and a second display area at a side of the first display area in a first direction;
data lines arranged in the first direction in the first display area and the second display area, the data lines extending in a second direction intersecting the first direction;
vertical connection lines arranged in the first direction in a sub-display area of the first display area adjacent to the second display area, the vertical connection lines extending in the second direction; and
horizontal connection lines configured to connect the vertical connection lines to the data lines in the second display area, the horizontal connection lines extending in the first direction,
wherein a number ratio of data lines and the vertical connection lines in the sub-display area is 1:2.

15. The display device of claim 14, wherein each of line groups includes a data line which is one of the data lines, a first vertical connection line which is one of the vertical connection lines and adjacent to a first side of the data line, and a second vertical connection line which is one of the vertical connection lines and adjacent to a second side of the data line, and
wherein the line groups are arranged in the first direction in the sub-display area.

16. The display device of claim 14, wherein the display panel is foldable along a folding line extending in the second direction between the first display area and the second display area.

17. The display device of claim 16, wherein a vertical connection line closest to the folding line among the vertical connection lines is electrically connected to a data line closest to the folding line among the data lines in the second display area, and
wherein a vertical connection line farthest from the folding line among the vertical connection lines is electrically connected to a data line farthest from the folding line among the data lines in the second display area.

18. The display device of claim 14, wherein a number of the data lines in the first display area and a number of the data lines in the second display area are the same.

19. The display device of claim 14, further comprising:
a data driving circuit positioned in the second direction from the first display area and electrically connected to the data lines in the first display area and the vertical connection lines.

20. An electronic device comprising:
one or more processors;
a memory connected to the one or more processors;
a power module connected to the one or more processors; and
a display device configured to receive input image data from the one or more processors and to display an image corresponding to the input image data, the display device comprising:
a display panel including a first display area, a second display area at a first side of the first display area in a first direction, and a third display area at a second side of the first display area in the first direction;
data lines arranged in the first direction in the first display area, the second display area, and the third display area, the data lines extending in a second direction intersecting the first direction;
vertical connection lines arranged in the first direction in the first display area, the vertical connection lines extending in the second direction; and
horizontal connection lines configured to connect the vertical connection lines to the data lines in the second display area or the third display area, the horizontal connection lines extending in the first direction,
wherein a number ratio of the data lines and the vertical connection lines in the first display area is 1:2.
